(19) United States
(12) Patent Application Publication
(10) Pub. No.: US 2017/0214225 A1
(43) Pub. Date: Jul. 27, 2017

(54) INTERCONNECT AND METERING FOR RENEWABLES, STORAGE AND ADDITIONAL LOADS WITH ELECTRONICALLY CONTROLLED DISCONNECT CAPABILITY FOR INCREASED FUNCTIONALITY

(71) Applicant: Locus Energy, Inc., Hoboken, NJ (US)

(72) Inventors: Anil Ramachandran, Santa Clara, CA (US); Ben Coquillette, San Francisco, CA (US); Shawn Kerrigan, Redwood City, CA (US)

(21) Appl. No.: 15/404,281

(22) Filed: Jan. 12, 2017

Related U.S. Application Data
(60) Provisional application No. 62/281,787, filed on Jan. 22, 2016.

(51) Int. Cl. H02B 1/24; G01R 21/133; H02J 9/06; H02H 7/20; H01R 31/06; H02B 1/46

(52) U.S. Cl. CPC H02B 1/24; H01R 31/06; H02B 1/46; H02J 9/06; H02H 7/20; G01R 21/133

(57) ABSTRACT

An interconnect box between a utility meter and a main service panel having at least two grid electrical inputs from the utility meter; at least one grid neutral input from the utility meter, wherein the grid electrical inputs and the grid neutral inputs are combined to provide a combined grid stream; at least two external electrical inputs having circuit breakers for each of the at least two electrical inputs; at least one external neutral input; at least one shorting block used to merge together two of the at least two external electrical inputs and one of the at least one external neutral inputs to provide an external merged stream; a central computing unit receives and utilizes power from at least one of the combined grid stream and the external merged stream to generate power and source voltage on energy metering.

This application claims the priority benefit under 35 U.S.C. §119(e) of U.S. Provisional Application No. 62/281,787 filed on Jan. 22, 2016, the disclosures of each of which are incorporated herein by reference in its entirety. The present disclosure generally relates to a combined interconnect, metering, and control box and a utility meter socket adapter for adapting the combined interconnect, metering, and control box to existing electrical infrastructure.

### TECHNICAL FIELD

### Background

In existing wiring, the power coming in from the grid passes through a utility Watt-Hour meter and proceeds to the main AC service panel. Both loads and sources are connected up to this through circuit breakers rated to the capacity of the load/source. In case the circuit breaker capacity of the panel was insufficient to meet the needs of the new loads/sources being installed, the main service panel would be replaced, or a subpanel would be added. If the wiring between the utility meter and the service panel or within the main service panel was not sufficiently rated to handle the total current including the newly interconnected loads/sources, the wiring would have to be upgraded.

Adding Solar, Storage, and EV charging to an existing home poses several challenges resulting from the fact that the electrical infrastructure in the home was not designed with these in mind. Problems include inadequate circuit breaker capacity in the main AC service panel, additional equipment required on each new branch of energy to meet code, new operational modes where a disconnection from the grid may be necessary to enable stored energy to power the home in case of a grid outage, requirement for backup power to critical loads in case of a grid outage etc. The present invention also enables new grid interactive features such as demand response, grid assist, time shifting of loads, and net export curtailment by being the nerve center of the distributed generation system.

The prior existing technology does not provide any branching. If there is power to the panel, it connects up to everything. If the panel is out of breaker capacity, you end up needing to replace it. You end up needing to add external disconnect switch/protection circuitry for each external source that is hooked up for safety. The prior existing technology also has no way of enabling a grid disconnect to facilitate islanded mode operation, either backing up the entire main service panel, or critical loads. The present invention also provides a meter socket adapter with load side interruption and terminals. This allows any control and monitoring equipment to be inserted between the utility meter and the main service panel which could otherwise be very complicated, especially in case of a combined main service panel—utility meter arrangement.

The first part of the invention describes a combined interconnect, metering, and control box that would solve all the issues mentioned above. The location of the interconnect, metering, and control box in between the utility meter and main service panel enables consumption metering, islanding for backup purposes, and supply side interconnect which eliminates the need to upgrade the main service panel.

The second part of the invention describes a utility meter socket adapter that would allow the combined interconnect, metering, and control box mentioned in the first part to be connected up without disturbing, replacing, or upgrading the existing electrical infrastructure in the home at all. The meter socket adapter allows for the interruption and exposing of terminals on the load side of the utility meter without affecting the wiring past the utility meter socket.

### SUMMARY OF THE INVENTION

The current invention provides an electrical interconnect and metering box for renewables, storage and additional loads comprising: an interconnect box between a utility meter and a main service panel of a property, wherein the interconnect box intercepts the electrical connection between the main service panel and the utility meter; at least two grid electrical inputs from the utility meter are connected to the interconnect box wherein the at least two grid electrical inputs are combined to provide a combined grid stream; at least two external electrical inputs connected to the interconnect box having circuit breakers for each of the at least two electrical inputs; at least one external neutral input connected to the interconnect box; at least one shorting block used to merge together two of the at least two external electrical inputs and one of the at least one external neutral inputs to provide an external merged stream; a central computing unit receives the combined grid stream and the external merged stream and utilizes power from at least one of the combined grid stream and the external merged stream to generate power and source voltage on energy metering, wherein the combined grid stream and the external merged stream from the central computing unit are connected through an electronically controlled disconnect switch and an emergency manual AC disconnect switch to a power distribution block that ties the external merged stream into the combined grid stream and the main service panel.

The current invention also provides a meter socket adapter having; a first housing with a bottom end and a top end; the bottom end having at least two line side electrical contacts and at least two load side electrical contacts; the top end having at least two line side receiving terminals and at least two load side receiving terminals, wherein each of the at least two line side electrical contacts are directly shorted to a corresponding one of the at least two line side receiving terminals, wherein each of the at least two load side electrical contacts and the at least two load side receiving terminals are isolated from each other; wherein the electrical interconnect and metering box has a first set of in connection terminals and a second set of out connection terminals; wherein each of the at least two load side electrical contacts are directly wired to the first set of in connection terminals; wherein each of the at least two load side receiving terminals are directly wired to the second set of out connection terminals and wherein each of the first set of in connection terminals are connected to the second set of out connection terminals to complete the circuit interrupted by the meter socket adapter.

### BRIEF DESCRIPTION OF THE DRAWINGS

In the following section, the present disclosure will be described with reference to exemplary embodiments illustrated in the figures, in which:

FIG. 1 depicts a full featured embodiment of the present invention;

FIG. 2 depicts a simplified embodiment of the present invention;

FIG. 3 depicts a simplified version of the present invention with support for grid backfeed and grid outage backup power for critical loads; and

FIG. 4 depicts a meter socket adapter according to the present invention.

### DETAILED DESCRIPTION

In the following detailed description, numerous specific details are set forth in order to provide a thorough understanding of the disclosure. However, it will be understood by those skilled in the art that the present disclosure may be practiced without these specific details. In other instances, well-known methods, procedures, components and circuits have not been described in detail so as not to obscure the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” or “according to one embodiment” (or other phrases having similar import) in various places throughout this specification are not necessarily all referring to the same embodiment. Furthermore, the particular features, structures, or characteristics may be combined in any suitable manner in one or more embodiments. Also, depending on the context of discussion herein, a singular term may include its plural forms and a plural term may include its singular form. Similarly, a hyphenated term (e.g., “transformer-rated,” “WiFi”, “on-site,” etc.) may be occasionally interchangeably used with its non-hyphenated version (e.g., “transformer rated,” “WiFi”, “on site,” etc.), and a capitalized entry (e.g., “Electrical Unit,” “Operative Module,” “Electrician Zone,” etc.) may be interchangeably used with its non-capitalized version (e.g., “electrical unit”, “operative module,” “electrician zone,” etc.). Such occasional interchangeable uses shall not be considered inconsistent with each other.

It is noted at the outset that the terms “coupled,” “operatively coupled,” “connected”, “connecting,” “electrically connected,” etc., are used interchangeably herein to generally refer to the condition of being electrically/electronically connected in an operative manner. Similarly, a first entity is considered to be in “communication” with a second entity (or entities) when the first entity electrically sends and/or receives (whether through wireline or wireless means) information signals (whether containing address, data, or control information) to/from the second entity regardless of the type (analog or digital) of those signals. It is further noted that various figures (including component diagrams) shown and discussed herein are for illustrative purpose only, and are not drawn to scale.

The terms “first,” “second,” etc., as used herein, are used as labels for nouns that they precede, and do not imply any type of ordering (e.g., spatial, temporal, logical, etc.) unless explicitly defined as such.

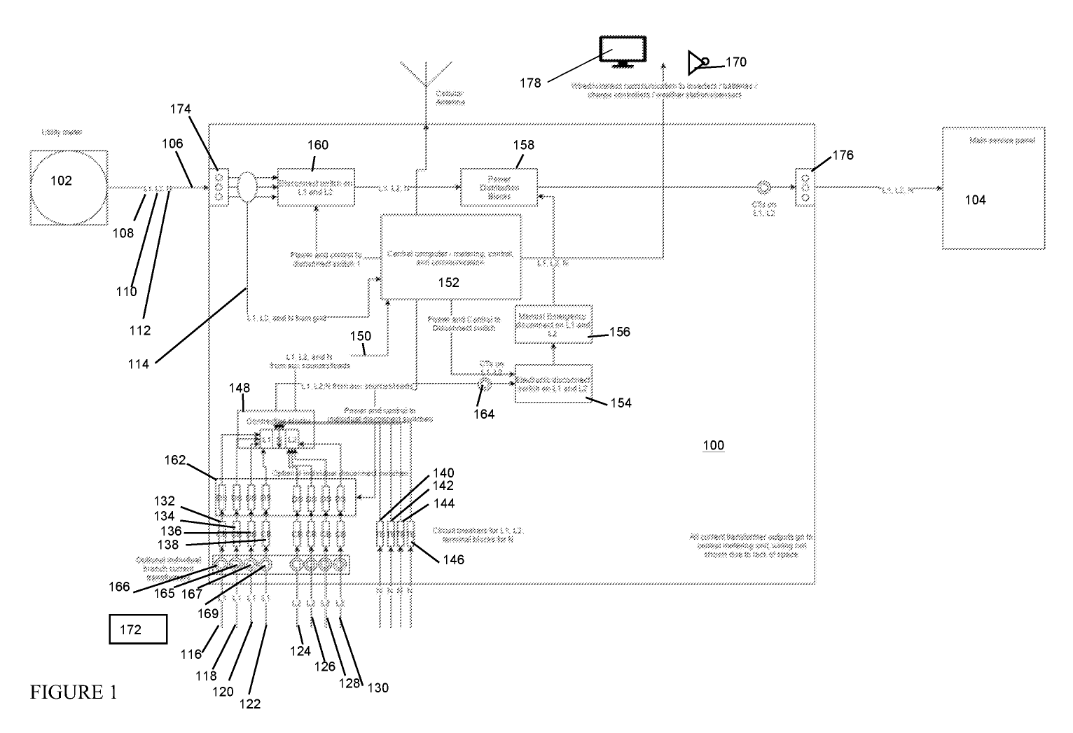

With reference to FIGS. 1-4, the physical structure electrical interconnect and metering box (100) is a NEMA rated box which would intercept the electrical connection between the utility meter and the main service panel. It would have circuit breakers for every external load or source that needs to connect to grid power. The box may have taps into the three split phase AC voltage lines (line1, line2, neutral) from the grid and/or the local generation side. It would also have current transformers around individual lines and/or the combined overall line before it is hooked up to grid power. In addition, current transformers would also be present around L1 and L2 on the service going to the main service panel to measure home consumption. It would have power distribution blocks that allow the external load/source lines to be hooked into the lines coming in from the grid. It could have a manual emergency disconnect switch that would isolate all external loads/sources from the grid power.

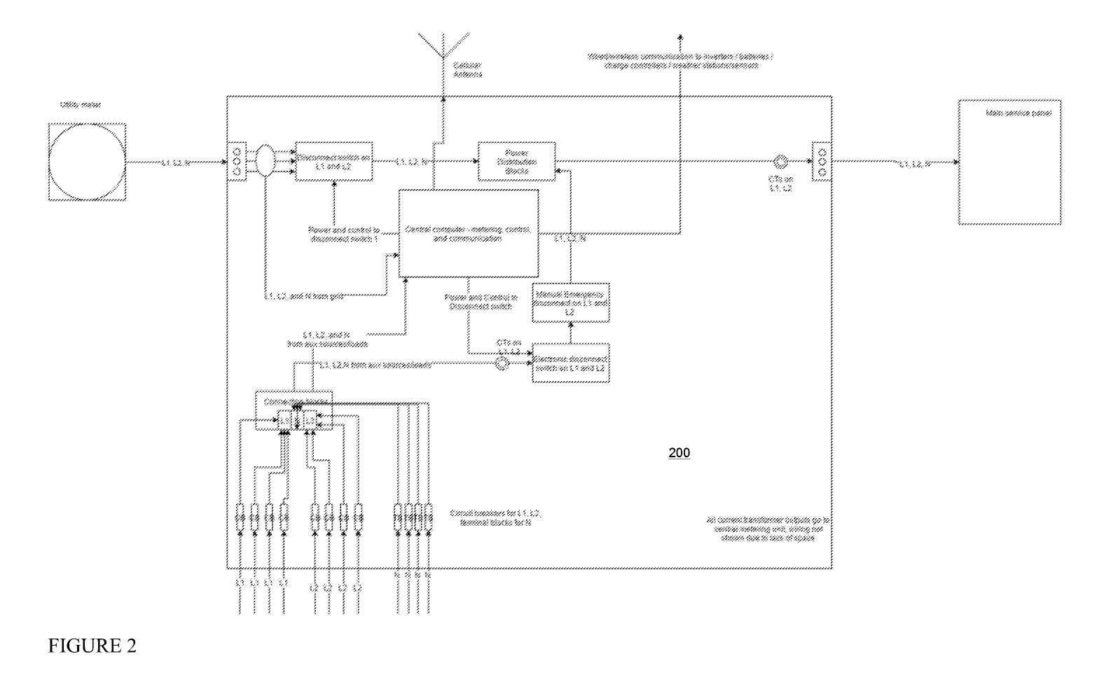

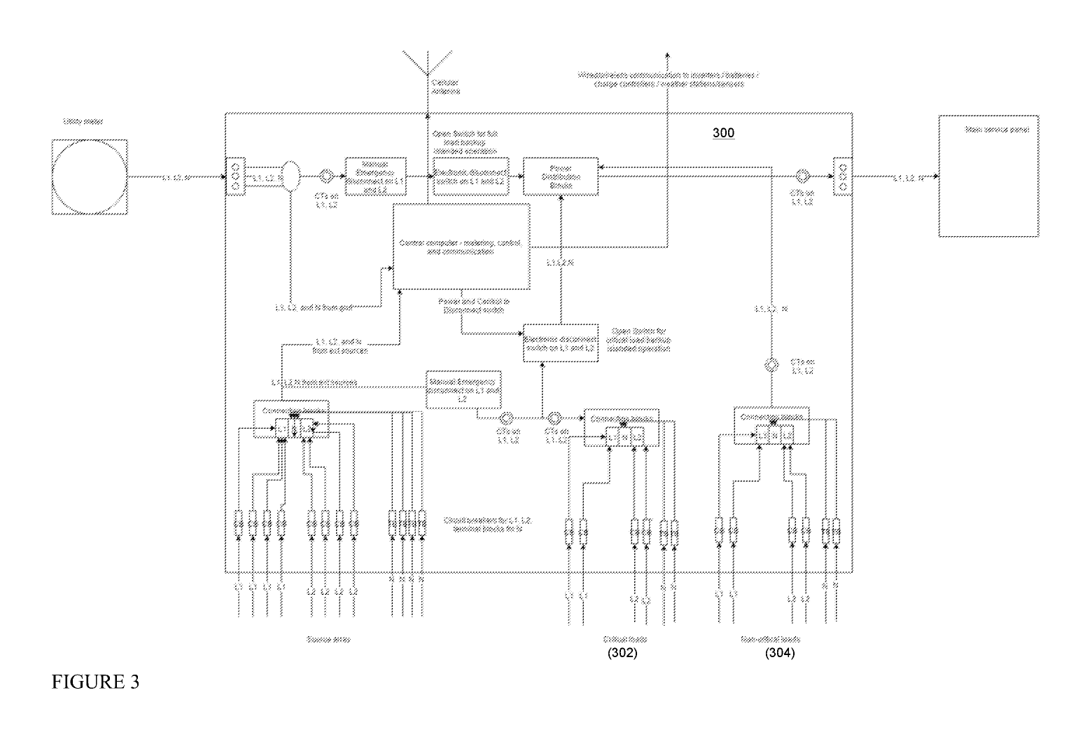

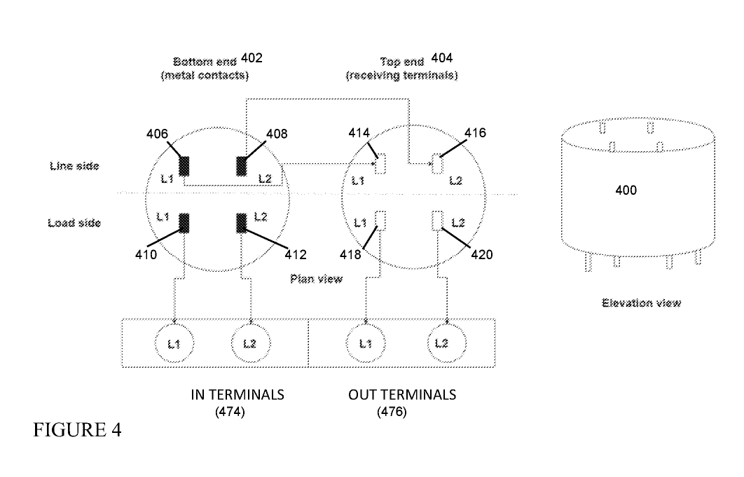

FIG. 1 depicts a full featured variant of the invention, it would have disconnect switches that allow disconnection of each external power source/load all at one go or individually. It would also have a disconnect switch that allows disconnection of utility power in case of a grid blackout to allow the use of stored energy or renewable generated energy as backup to the entire main service panel in the absence of grid power. FIG. 2 depicts a simplified version of the invention, there are no CTs or disconnect switches on the individual lines from each load/source. FIG. 3 depicts a simplified interconnect box with support for grid backfeed and grid outage backup power for critical loads. In this version, sources, critical loads, and non-critical loads have been separated. Emergency disconnect switches are provided for grid and external sources. Electronic disconnects are present at two locations. Optional CTs are present at the external loads, critical loads, non-critical loads, incoming grid source, and the through connection to the main service panel. FIG. 4 depicts a meter socket adapter.

The invention includes a central metering, communication, and computing unit which collects all data, communicates to the server, performs all computations as well as any control functions required. To prevent the control functions from islanding and removing power from the device, the unit shall have redundant power supplies allowing it to function from power either from the grid or from any of the sources connected up to it. The device shall also be capable of sensing whether the grid is live or not, whether or not it is powered from it. L1, L2, and N from one or more loads or sources is connected up to the box. Each L1 or L2 input is hooked up through a circuit breaker, optionally a disconnect switch, and optionally a current transformer. Neutrals are directly connected up. Past these, shorting blocks are used to merge together L1, L2, and N streams. L1 and L2 from this point are connected up to L1 and L2 from the grid through an electronically controlled disconnect switch and an emergency manual AC disconnect. In some variants, the L1 and L2 streams from loads is kept separate from the L1 and L2 streams from sources to enable independent metering of loads and sources as well as independent disconnection of loads and sources as required. This is facilitated by separate current transformers and disconnect switches/contactors on the combined load L1 and L2 as well as the combined source L1 and L2. The disconnect switches are controlled based on internal logic and rules or remotely sent commands to achieve multiple functional goals. Past the merging point of all external L1, L2, and N streams, the combined stream of external L1 and L2 are shorted to the utility incoming L1 and L2 using Power distribution/shorting blocks. Current transformers measuring the total external load/source current on L1 and L2 may be used at this point instead of or in addition to individual branch current measurements.

The power coming in from the utility meter passes through optional disconnect switches for L1 and L2 into the same power distribution blocks where it merges with the external combined L1 and L2. Past the blocks, these lines continue onto a second set of terminal blocks through current transformers on L1 and L2. L1, L2, and N are connected from this second terminal block to the main AC service panel. L1, L2, and N are tapped from the incoming utility source and connected to the central measurement, computing, control, and communication unit. A second stream of L1, L2, and N are tapped from the combined external load/source power and connected up as well.

The central unit is capable of using power from either source to generate its own power, as well as using either source for the voltage on energy metering. It will also be capable of independently monitoring both streams for presence of electrical energy delivery. In addition, all variants would also be capable of being powered from a DC backup power output from a renewable source that can be safely active even if the grid goes down (not shown in diagrams). All variants would also include communications capabilities allowing them to communicate with equipment on site that generate or consume the external source/loads as well as with an external information, control and data acquisition server. The full featured version, as depicted in FIG. 1, has disconnect switches on L1 and L2 for each external load/source. It also has current transformers on L1 and L2 for each external load/source or in some cases only on one of the branches when the load is balanced across L1 and L2. An installer would be able to use an interface to configure which connection pairs/sets define each load/source and group CTs if required to define a specific load. This variant supports the full main service panel islanded mode backup option. There are several ways of implementing this including but not limited to: (1) By rapidly opening the grid power disconnect switch as soon as a grid outage is detected and communicating with the renewable sources to confirm disconnection from the grid to enable them to continue to generate AC power. When grid power returns, the box will close the switch automatically with/without before/after informing the renewable source with or without permission from the renewable source to do so. (2) When the grid outage happens, the renewable source(s) rapidly shut down their AC output, however, they still keep the DC backup power to the box active which continues to power the box. Upon detection of grid outage, the inverter will start a protocol to command the box to open the grid disconnect. The box will follow this and confirm this to the renewable source which will now resume AC generation. In this case, on return of grid power, the box will inform the renewable source of this and the renewable source will command the box to close the switch after it performs the necessary steps to handle the return of grid power.

FIG. 2 depicts the simplified interconnect box (200) retaining islanded mode backup for full main service panel. This takes the full featured variant and removes the individual load/source disconnect switches and current transformers but retains all other features including the ability to disconnect from the grid and allow the renewable source(s) to act as a power source to the entire main service panel.

FIG. 3 depicts a simplified interconnect box (300) with support for grid backfeed and grid outage backup power for critical loads. This design serves the purpose of allowing the connecting up of critical loads as well as additional non-critical loads that would not fit within the capacity limitations of the main service panel. Two emergency disconnects allow disconnection of grid source power and external power sources. An electronic disconnect switch that disconnects the sources and critical loads from the grid allows islanded mode backup power for critical loads only. A separate disconnect switch that cuts off grid power enables islanded mode backup power for all loads. CTs around the five separate power paths allow metering of external sources, critical loads, non-critical loads on this panel, main service panel load, as well as grid sourced power. For islanded mode operation with critical load only backup, in case of a grid outage, the electronic disconnect switch isolating the external sources and critical loads from grid power is opened (either automatically and rapidly on detection of grid outage by the box, or following commanding by the renewable source after it has performed the rapid shutdown as described in section 1). Once the electronic disconnect switch is opened, the renewable sources are able to power the critical loads connected to the load array. For islanded mode operation with full load backup, in case of a grid outage, the electronic disconnect switch on the grid supply is opened (either automatically and rapidly on detection of grid outage by the box, or following commanding by the renewable source after it has performed the rapid shutdown as described in section 1). Once the electronic disconnect switch is opened, the renewable sources are able to power all loads connected to the critical load array, the non-critical load array, as well as the main service panel. In both cases, upon return of power, the box closes the disconnect switch to return to normal operation mode, possibly in coordination with the renewable source.

An electrical interconnect and metering box for renewables, storage and additional loads is provided having an interconnect box (100) between a utility meter (102) and a main service panel (104) of a property, wherein the interconnect box intercepts the electrical connection between (106) the main service panel and the utility meter; at least two grid electrical inputs (108, 110 also circuit diagram marked as L1, L2) from the utility meter are connected to the interconnect box (100). At least one of the at least two grid electrical inputs may be a grid neutral input (112 also circuit diagram marked as N) from the utility meter is connected to the interconnect box (100), wherein the at least two grid electrical inputs (including the at least one grid neutral inputs if present) are combined to provide a combined grid stream (114). Note that a split phase system is typically in use in the US. Internationally, the at least two grid electrical inputs may consist of only one grid electrical input line and a grid neutral input. It is also noted that a three phase service could have only three live grid conductors and no neutral. Having the neutral is not essential to the invention, and would perform the same functions (metering, disconnect, islanding) as a three phase service the same way. At least two external electrical inputs (e.g. 116, 118, 120, 122, 124, 126, 128, 130 also circuit diagram marked as L1, L2) connected to the interconnect box having circuit breakers (e.g. 132, 134, 136, 138) for each of the at least two electrical inputs; at least one external neutral input (e.g. 140, 142, 144 and 146 also marked as circuit diagram N) connected to the interconnect box; at least one shorting block (148) used to merge together two of the at least two external electrical inputs and one of the at least one external neutral inputs to provide an external merged stream (150); a central computing unit (150) receives the combined grid stream (114) and the external merged stream (150) and utilizes power from at least one of the combined grid stream and the external merged stream to generate power and source voltage on energy metering, wherein the combined grid stream (114) and the external merged stream from the central computing unit (150) are connected through an electronically controlled disconnect switch (154) and an emergency manual AC disconnect switch (156) to a power distribution block (158) that ties the external merged stream (150) into the combined grid stream (114) and the main service panel (104).

There may be a disconnect switch (e.g. 160, 162, 154, 156) on at least one of the grid electrical inputs (e.g. disconnect switch 160), the external electrical inputs (e.g disconnect switch(es) 162), the combined grid stream and the external merged stream. The disconnect switches may be controlled by at least one of internal rules, internal logic and remote commands. There may be grid disconnect switch (160) for the at least two grid electrical inputs from the utility meter, wherein the grid disconnect switch rapidly opens as soon as grid outage is detected to enable a renewable source to continue to generate AC power.

Each of the at least two external electrical inputs may have a disconnect switch and a current transformer. An external merged stream may be load balanced and a current transformer may be on one of at least two external electrical inputs. There may also be a current transformer (e.g. 164, 166) on at least one of the grid electrical inputs, the external electrical inputs, the combined grid stream and the external merged stream. There may be a DC backup power from a renewable source in communication with the central computing unit, wherein the central computing unit utilizes power from the DC backup power in the event of a grid outage. There may also be a communication link between the central computing unit and at least one of an inverter, batteries, charge controllers, weather stations and sensors.

As shown in FIG. 3, critical loads (302) and non-critical loads (304) may be separated and critical loads are supplied power from the DC backup power in the event of a grid outage. The interconnect box (100) may be in communication with an inverter (170) upon detection of a grid outage the central computing unit (100) of the interconnect box directs a renewable source (172) to shut down AC output and keep a DC backup power to the interconnect box (100) and the inverter (170) will start a protocol to command the interconnect box (100) to open the grid disconnect and confirm this to the renewable source (172) which would resume AC generation; wherein upon detection of a return of grid power, the central computing unit (152) of the interconnect box (100) informs the renewable source of the return of grid power and the renewable source will command the central computing unit (152) of the interconnect box (100) to close the DC backup power to the interconnect box and return to grid power.

There may be an installer interface (178) in communication with the central computing unit, wherein the installer interface allows an installer to configure the at least two external electrical inputs (108, 110) connected to the interconnect box to define a load or a source. There may be at least two current transformers (e.g. 165, 166, 167, 169) and an installer interface (178) in communication with the central computing unit (152), the installer interface (178) allows an installer to group together at least two current transformers (e.g. 165, 166, 167, 169) to define a specific load.

FIG. 4 depicts a meter socket adapter (400) having; a first housing with a bottom end (402) and a top end (404); the bottom end (402) having at least two line side electrical contacts (406, 408) and at least two load side electrical contacts (410, 412); the top end (404) having at least two line side receiving terminals (414, 416) and at least two load side receiving terminals (418, 420). Each of the at least two line side electrical contacts (406, 408) are directly shorted to a corresponding one of the at least two line side receiving terminals (414, 416). As can be seen line side electrical contact (406) is directly shorted to line side receiving terminal (414) and line side electrical contact (408) is directly shorted to line side receiving terminal (416). Each of the at least two load side electrical contacts (410, 412) and the at least two load side receiving terminals (418, 420) are isolated from each other. The meter socket adapter has a first set of in connection terminals (474) and a second set of out connection terminals (476). Each of the at least two load side electrical contacts (410,412) are directly wired to the first set of in connection terminals (474) and each of the at least two load side receiving terminals (418, 420) are directly wired to the second set of out connection (476) terminals and wherein each of the first set of in connection terminals (474) are expected to be connected to the second set of out connection terminals (476) to complete the circuit interrupted by the meter socket adapter. There may be any number of terminals and contacts. The number of in connection terminals in the first set of in connection terminals may be equal to the number of load side electrical contacts. The number of out connection terminals in the second set of out connection terminals may be equal to the number of load side receiving terminals. Each of the first set of in connection terminals (474) may be directly connected by a conductor to the second set of out connection terminals (476). Alternatively, of the first set of in connection terminals (474) are connected through the interconnect box to the second set of out connection terminals (476). This may be accomplished by wiring the “IN” connection terminals on the meter socket adapter (474) to the main service panel side of the interconnect and metering box (176) and the “OUT” connection terminals on the meter socket adapter (476) to the utility meter side of the interconnect and metering box (174). This may be accomplished with a conductor contained in the interconnect box. There may also be a disconnect switch for each of the at least two external electrical inputs connected to the interconnect box and at least one current transformer on at least one of the at least two external electrical inputs.

To enable islanding from grid in order to provide backup power from storage, the power needs to be able to interrupt the power from the grid. This means a meter socket adapter that simply hooks into and exposes connection terminals or wires that connect to the power lines is no longer sufficient. Similarly, in order to monitor consumption, the adapter has to actually interrupt the flow and bring out the flow to pass through a conductor the current through which can be metered.

This invention describes a meter socket adapter that interrupts the power flow on the home side of the meter and brings out both ends of the interrupt as connection terminals. The socket meter adapter would have electrical contacts at the bottom that plug into an existing meter socket for a utility meter. It would have receiving electrical terminals at the top into which another meter could plug in. On the line side, each electrical contact at the bottom would be directly shorted to the corresponding receiving terminal at the top with an adequately rated conductor. On the load side, the electrical contacts and receiving terminals are isolated from one another. All of the above shall be in the first housing. In the interconnect box, there may be two sets of connection terminals. Each set of connection terminals would have the same number of contacts as there are on the load side. One set shall be called OUT and the top layer load side contacts shall be directly wired to this set of terminals. The second set shall be called IN and the bottom layer load side receiving terminals would be directly wired into this second set of terminals. To complete the circuit interrupted by the socket adapter, each terminal from the IN section would need to be directly connected to the corresponding terminal from the OUT section using an adequately rated conductor. Instead of directly connecting them, such connection may be made through an interconnect, monitoring, and control box as described in the first part of this disclosure. Such a connection enables consumption metering, islanding, as well as additional loads/sources interconnect. FIG. 4 shows an example implementation with two lines (L1 and L2) but the invention could extend to any meter socket with any number of terminals and contacts. The meter socket adapter has no dynamic functionality. It is prewired and simply interrupts the electrical connection past the utility meter and provides an interconnect point to hook monitoring, control, and interconnect equipment in line with the electrical grid connection into the home without disturbing, replacing, or upgrading electrical wiring and equipment.

The present invention increases demand response, grid assist, time shifting of loads, and net export curtailment. It allows the ability to interconnect renewables and storage easily behind the meter without disturbing, replacing, or upgrading electrical wiring and equipment in the home allows the system to engage in these grid interactive operations to generate maximum value. Moreover, as long as the interconnect box, the meter enclosure, and the meter itself can handle the combined maximum amperage of the connected sources and loads, the rest of the electrical system needs to only be sized to handle their max load before solar/storage was introduced into the picture. Loads and sources connected to the interconnect box can freely source or sink current to their maximum capability without issue.

As will be recognized by those skilled in the art, the innovative concepts described in the present application can be modified and varied over a wide range of applications. Accordingly, the scope of patented subject matter should not be limited to any of the specific exemplary teachings discussed above, but is instead defined by the following claims.

What is claimed is:

1. An electrical interconnect and metering box for renewables, storage and additional loads comprising:
an interconnect box between a utility meter and a main service panel of a property, wherein the interconnect box intercepts the electrical connection between the main service panel and the utility meter;
at least two grid electrical inputs from the utility meter are connected to the interconnect box wherein the at least two grid electrical inputs are combined to provide a combined grid stream;
at least two external electrical inputs connected to the interconnect box having circuit breakers for each of the at least two electrical inputs;
at least one external neutral input connected to the interconnect box;
at least one shorting block used to merge together two of the at least two external electrical inputs and one of the at least one external neutral inputs to provide an external merged stream;
a central computing unit receives the combined grid stream and the external merged stream and utilizes power from at least one of the combined grid stream and the external merged stream to generate power and source voltage on energy metering, wherein the combined grid stream and the external merged stream from the central computing unit are connected through an electronically controlled disconnect switch and an emergency manual AC disconnect switch to a power distribution block that ties the external merged stream into the combined grid stream and the main service panel.

2. An electrical interconnect and metering box as in claim 1, further comprising a disconnect switch on at least one of the grid electrical inputs, the external electrical inputs, the combined grid stream and the external merged stream.

3. An electrical interconnect and metering box as in claim 1, further comprising a current transformer on at least one of the grid electrical inputs, the external electrical inputs, the combined grid stream and the external merged stream.

4. An electrical interconnect and metering box as in claim 2, wherein the disconnect switches are controlled by at least one of internal rules, internal logic and remote commands.

5. An electrical interconnect and metering box as in claim 1, further comprising a DC backup power from a renewable source in communication with the central computing unit, wherein the central computing unit utilizes power from the DC backup power in the event of a grid outage.

6. An electrical interconnect and metering box as in claim 5, wherein critical loads and non-critical loads are separated and critical loads are supplied power from the DC backup power in the event of a grid outage.

7. An electrical interconnect and metering box as in claim 1, wherein each of the at least two external electrical inputs has a disconnect switch and a current transformer.

8. An electrical interconnect and metering box as in claim 3, wherein an external merged stream is load balanced and a current transformer is on one of at least two external electrical inputs.

9. An electrical interconnect and metering box as in claim 1, further comprising a communication link between the central computing unit and at least one of an inverter, batteries, charge controllers, weather stations and sensors.

10. An electrical interconnect and metering box as in claim 1, wherein the interconnect box has a grid disconnect switch for the at least two grid electrical inputs from the utility meter, wherein the grid disconnect switch rapidly opens as soon as grid outage is detected to enable a renewable source to continue to generate AC power.

11. An electrical interconnect and metering box as in claim 1, wherein the interconnect box is in communication with an inverter,
wherein upon detection of a grid outage the central computing unit of the interconnect box directs a renewable source to shut down AC output and keep a DC backup power to the interconnect box and the inverter will start a protocol to command the interconnect box to open the grid disconnect and confirm this to the renewable source which would resume AC generation;
wherein upon detection of a return of grid power, the central computing unit of the interconnect box informs the renewable source of the return of grid power and the renewable source will command the central computing unit of the interconnect box to close the DC backup power to the interconnect box and return to grid power.

12. An electrical interconnect and metering box as in claim 1, further comprising a meter socket adapter having;
a first housing with a bottom end and a top end;
the bottom end having at least two line side electrical contacts and at least two load side electrical contacts;
the top end having at least two line side receiving terminals and at least two load side receiving terminals,
wherein each of the at least two line side electrical contacts are directly shorted to a corresponding one of the at least two line side receiving terminals,
wherein each of the at least two load side electrical contacts and the at least two load side receiving terminals are isolated from each other;
wherein the electrical interconnect and metering box has a first set of in connection terminals and a second set of out connection terminals;
wherein each of the at least two load side electrical contacts are directly wired to the first set of in connection terminals;
wherein each of the at least two load side receiving terminals are directly wired to the second set of out connection terminals and
wherein each of the first set of in connection terminals are connected to the second set of out connection terminals to complete the circuit interrupted by the meter socket adapter.

13. An electrical interconnect and metering box as in claim 12, wherein the number of in connection terminals in the first set of in connection terminals is equal to the number of load side electrical contacts.

14. An electrical interconnect and metering box as in claim 12, wherein the number of out connection terminals in the second set of out connection terminals is equal to the number of load side receiving terminals.

15. An electrical interconnect and metering box as in claim 12, wherein each of the first set of in connection terminals are directly connected by a conductor to the second set of out connection terminals.

16. An electrical interconnect and metering box as in claim 12, wherein each of the first set of in connection terminals are connected through the interconnect box to the second set of out connection terminals.

17. An electrical interconnect and metering box as in claim 1, further comprising a disconnect switch for each of the at least two external electrical inputs connected to the interconnect box and at least one current transformer on at least one of the at least two external electrical inputs.

18. An electronical interconnect and metering box as in claim 17, further comprising an installer interface in communication with the central computing unit, wherein the installer interface allows an installer to configure the at least two external electrical inputs connected to the interconnect box to define a load or a source.

19. An electronical interconnect and metering box as in claim 17, wherein there are at least two current transformers and further comprising an installer interface in communication with the central computing unit, wherein the installer interface allows an installer to group together at least two current transformers to define a specific load.

20. An electrical interconnect and metering box as in claim 1, wherein at least one of the at least two grid electrical inputs is a grid neutral input from the utility meter connected to the interconnect box.

21. An electronical interconnect and metering box as in claim 20, wherein at least two of the electrical inputs from the utility meter and at least one grid neutral input from the utility meter are from a three split phase AC voltage line.

22. An electronical interconnect and metering box as in claim 1, wherein at least two of the two external electrical inputs and at least one external neutral input are from a three split phase AC voltage line.
